(19) United States
(12) Patent Application Publication
(10) Pub. No.: US 2024/0055506 A1
(43) Pub. Date: Feb. 15, 2024

(54) MANUFACTURING METHOD OF SEMICONDUCTOR DEVICE AND SEMICONDUCTOR DEVICE

(71) Applicant: FUJI ELECTRIC CO., LTD., Kanagawa (JP)

(72) Inventors: Takashi YOSHIMURA, Matsumoto-city (JP); Makoto SHIMOSAWA, Matsumoto-city (JP); Motoyoshi KUBOUCHI, Matsumoto-city (JP); Misaki UCHIDA, Matsumoto-city (JP)

(21) Appl. No.: 18/491,832

(22) Filed: Oct. 23, 2023

Related U.S. Application Data
(63) Continuation of application No. PCT/JP2022/036682, filed on Sep. 30, 2022.

(30) Foreign Application Priority Data
Nov. 10, 2021 (JP) 2021-183645

(51) Int. Cl. H01L 29/739; H01L 29/66; H01L 27/07; H01L 29/861; H01L 21/266; H01L 29/06

(52) U.S. Cl. CPC H01L 29/7397; H01L 29/66348; H01L 27/0727; H01L 29/861; H01L 21/266; H01L 29/0696

(57) ABSTRACT

To provide a manufacturing method of a semiconductor device including forming a lifetime control region from the side of a front surface of a semiconductor substrate, ion-implanting Ti into a bottom surface of a contact hole provided so as to penetrate through an interlayer dielectric film arranged on the front surface of the semiconductor substrate, and forming a Ti silicide layer at the bottom surface of the contact hole with anneal.

The contents of the following Japanese patent application(s) are incorporated herein by reference:

No. 2021-183645 filed in JP on Nov. 10, 2021; and

No. PCT/JP2022/036682 filed in WO on Sep. 30, 2022

### TECHNICAL FIELD

The present invention relates to a manufacturing method of a semiconductor device and a semiconductor device.

### BACKGROUND

Conventionally, a technique of, in a semiconductor device where a transistor portion such as an insulated gate bipolar transistor (IGBT) and a diode portion are formed on a same substrate, irradiating a particle beam such as a helium ion to a position of a predetermined depth of the semiconductor substrate, and providing a lifetime control region including a lifetime killer, has been known (for example, see Patent document 1).

### PRIOR ART DOCUMENT

### Patent Document

Patent Document 1: Japanese Patent Application Publication No. 2017-135339

### Problem to be Solved

In such semiconductor device, there has been a problem of a decreased threshold voltage in a boundary portion in direct contact with the diode portion of the transistor portion.

### BRIEF DESCRIPTION OF THE DRAWINGS

FIG. 1 illustrates an example of a top view of a semiconductor device 100 according to an embodiment.

FIG. 2 illustrates an example of an enlarged view of a region A in FIG. 1.

FIG. 3 is a drawing illustrating an example in a cross-section a-a′ of FIG. 2.

FIG. 4A illustrates an enlarged cross-sectional view of a semiconductor device 200 according to a comparative example.

FIG. 4B illustrates an example of an enlarged cross-sectional view of the semiconductor device 100 according to the embodiment.

FIG. 5A is a drawing illustrating an example of a manufacturing method of the semiconductor device 100 according to the embodiment.

FIG. 5B is a drawing illustrating an example of the manufacturing method of the semiconductor device 100 according to the embodiment.

FIG. 5C is a drawing illustrating another example of the manufacturing method of the semiconductor device 100 according to the embodiment.

FIG. 6 is a drawing illustrating a relationship between an implantation acceleration voltage and an implantation depth of Ti ions.

FIG. 7 illustrates an example of an enlarged cross-sectional view of the semiconductor device 100 according to the embodiment.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

In the present specification, one side in a direction parallel to a depth direction of a semiconductor substrate is referred to as an “upper” side, and another side is referred to as a “lower” side. One of two main surfaces of a substrate, a layer, or other members is referred to as an “upper surface”, and another surface is referred to as a “lower surface”. “Upper”, “lower”, “front”, and “back” directions are not limited to a direction of gravity, or a direction of an attachment to a substrate or the like when a semiconductor device is mounted.

In the present specification, technical matters may be described with orthogonal coordinate axes consisting of an X axis, a Y axis, and a Z axis. In the present specification, a plane parallel to a front surface of the semiconductor substrate is referred to as an XY plane and a depth direction of the semiconductor substrate is referred to as the Z axis. Note that, as used in the present specification, the view of the semiconductor substrate in the Z axis direction is referred to as a planar view.

Each embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each embodiment respectively have opposite polarities.

In the present specification, in a layer or a region specified with N or P, electrons or holes are meant to be majority carriers, respectively. In addition, a layer or region denoted by the symbol “+” or “−” attached to the character N or P represents that the layer or region has a higher doping concentration or a lower doping concentration respectively, than a layer or region without this symbol. Further, the symbol “++” represents that a doping concentration is higher than “+”, and the symbol “−−” represents that a doping concentration is lower than “−”.

In the present specification, a doping concentration refers to a concentration of a donor or an acceptorized dopant. Therefore, the unit is/cm³. In the present specification, a difference of concentrations of a donor and an acceptor (i.e., a net doping concentration) may be set to be the doping concentration. In this case, the doping concentration can be measured by an SR method. Moreover, a chemical concentration of the donor and the acceptor may also be set to be a doping concentration. In this case, the doping concentration can be measured by an SIMS method. Unless otherwise limited, any one of the above may be used as a doping concentration. Unless otherwise limited, a peak value of a doping concentration distribution in a doping region may be set to be a doping concentration in the doping region.

In addition, in the present specification, the term “dosage” refers to the number of ions implanted into a wafer per unit area during ion implantation. Therefore, the unit is/cm². Note that a dosage of a semiconductor region can be taken as an integral concentration which is obtained by integrating doping concentrations across the semiconductor region in the depth direction. The unit of the integral concentration is/cm². Therefore, the dosage may be treated as the same as the integral concentration. The integral concentration may also be set to be an integral value within a half-value width. In the case of being overlapped by spectrum of another semiconductor region, the integral concentration may be derived without the influence of another semiconductor region.

Therefore, as used in the present specification, the level of the doping concentration can be read as the level of the dosage. That is, if the doping concentration of one region is higher than the doping concentration of another region, it can be understood that the dosage of the one region is higher than the dosage of the another region.

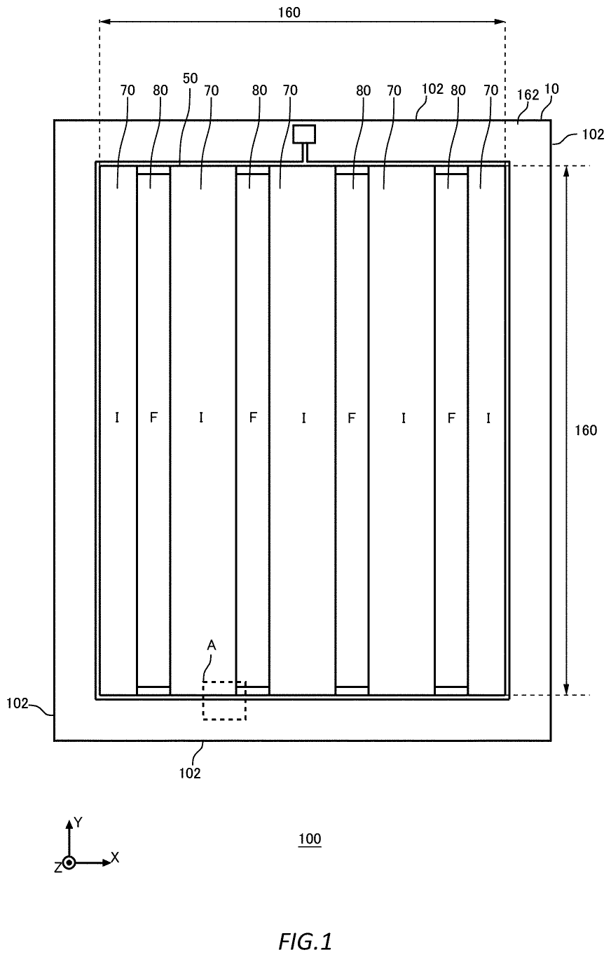

FIG. 1 illustrates an example of a top view of a semiconductor device 100 according to the embodiment. FIG. 1 illustrates a position of each member as being projected onto a front surface of a semiconductor substrate 10. FIG. 1 illustrates merely some members of the semiconductor device 100, and omits illustrations of some members.

The semiconductor device 100 includes the semiconductor substrate 10. The semiconductor substrate 10 has an end side 102 in a top view. As simply used in the present specification, a top view means a view from the side of the front surface of the semiconductor substrate 10. The semiconductor substrate 10 in the present example has two sets of end sides 102 facing each other in a top view. In FIG. 1, the X axis and the Y axis are parallel to any of the end sides 102. In addition, the Z axis is perpendicular to the front surface of the semiconductor substrate 10.

In the semiconductor substrate 10, an active region 160 is provided. The active region 160 refers to a region where main currents flow in the depth direction between the front surface and the back surface of the semiconductor substrate 10, when the semiconductor device 100 is operated. Above the active region 160, an emitter electrode is provided, but it is omitted in FIG. 1.

The active region 160 is provided with a transistor portion 70 including a transistor element such as an IGBT and a diode portion 80 including a diode element such as a free wheel diode (FWD). For example, the semiconductor device 100 is a reverse conducting IGBT (RC-IGBT). Note that the semiconductor device 100 may be an IGBT or an MOS transistor.

In the example of FIG. 1, transistor portions 70 and diode portions 80 are alternately arranged along a predetermined arrangement direction (the X axis direction in the present example) of the front surface of the semiconductor substrate 10. In another example, only the transistor portions 70 may be provided in the active region 160.

In FIG. 1, a region where each of the transistor portions 70 is arranged is represented by a symbol “I”, and a region where each of the diode portions 80 is arranged is represented by a symbol F. In the present specification, a direction perpendicular to the arrangement direction in a top view may be referred to as an extending direction (the Y axis direction in FIG. 1). Each of the transistor portions 70 and the diode portions 80 may have a longitudinal length in the extending direction. In other words, a length of each of the transistor portions 70 in the Y axis direction is greater than a width in the X axis direction. Similarly, a length of each of the diode portions 80 in the Y axis direction is greater than a width in the X axis direction. The extending direction of the transistor portion 70 and the diode portion 80, and the longitudinal direction of each trench portion described below may be the same.

In FIG. 1, an end portion of the transistor portion 70 in the Y axis direction is positioned closer to the end side 102 than an end portion of the diode portion 80 in the Y axis direction. In addition, the width of the transistor portion 70 in the X axis direction is greater than the width of the diode portion 80 in the X axis direction.

The diode portion 80 has a cathode region of the N+ type in a region in contact with the back surface of the semiconductor substrate 10. In the present specification, a region where the cathode region is provided is referred to as the diode portion 80. In other words, the diode portion 80 is a region that overlaps the cathode region in a top view. The back surface of the semiconductor substrate 10 may be provided with a collector region of the P+ type in a region other than the cathode region.

The transistor portion 70 has the collector region of the P+ type in a region in contact with the back surface of the semiconductor substrate 10. In addition, the transistor portion 70 includes emitter regions of the N type, base regions of the P type, and gate trench portions having gate conductive portions and gate dielectric films which are periodically arranged on the side of the front surface of the semiconductor substrate 10.

The semiconductor device 100 may have one or more pads above the semiconductor substrate 10. As an example, the semiconductor device 100 may also have pads such as a gate pad, an anode pad, a cathode pad and a current sense pad. Each pad is arranged in the vicinity of the end side 102. The vicinity of the end side 102 refers to a region between the end side 102 and the emitter electrode in a top view. When the semiconductor device 100 is mounted, each pad may be connected to an external circuit via wiring such as a wire.

A gate metal layer 50 is arranged between the active region 160 and the end side 102 of the semiconductor substrate 10 in a top view. The gate metal layer 50 connects the gate trench portion and the gate pad. The gate metal layer 50 in the present example surrounds the active region 160 in a top view. A region surrounded by the gate metal layer 50 in a top view may be referred to as the active region 160.

The semiconductor device 100 of the present example includes an edge terminal structure portion 162 between the active region 160 and the end side 102. The edge terminal structure portion 162 in the present example is arranged between the gate metal layer 50 and the end side 102. The edge terminal structure portion 162 reduces concentration of electric fields on the side of the front surface of the semiconductor substrate 10. The edge terminal structure portion 162 may have a plurality of guard rings. The guard ring is a region of the P type in contact with the front surface of the semiconductor substrate 10. By providing the plurality of guard rings, it is possible to extend a depletion layer on the side of the upper surface of the active region 160 outward. The withstand voltage of the semiconductor device 100 can be improved. The edge terminal structure portion 162 may further include at least one of a field plate or an RESURF provided in a circular form surrounding the active region 160.

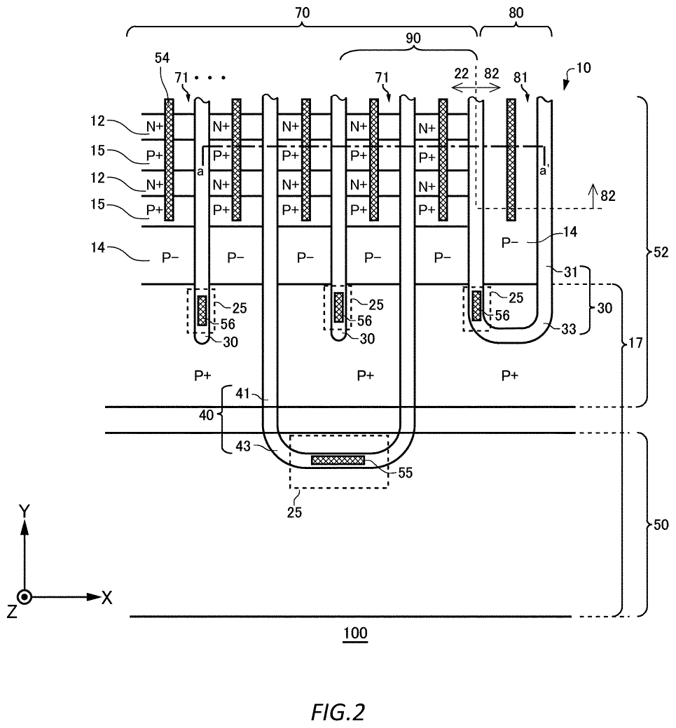

FIG. 2 is an enlarged view which illustrates an example of a region A in FIG. 1. The region A is a periphery of a boundary of the transistor portion 70 and the diode portion 80 in an edge side of the negative side in the Y axis direction of the semiconductor device 100, in a top view.

The transistor portion 70 is a region where a collector region 22 provided on the side of the back surface of the semiconductor substrate 10 is projected onto the front surface of the semiconductor substrate 10. The collector region 22 in the present example is of the P+ type as an example. The transistor portion 70 includes transistors such as IGBTs. The transistor portion 70 includes a boundary portion 90 positioned at the boundary between the transistor portion 70 and the diode portion 80. The boundary portion 90 is a region provided in a mesa portion of the transistor portion 70 which is adjacent to the diode portion 80 and does not operate as a transistor.

The diode portion 80 is a region where a cathode region 82 provided on the side of the back surface of the semiconductor substrate 10 is projected onto the front surface of the semiconductor substrate 10. The cathode region 82 in the present example is of the N+ type as an example. The diode portion 80 includes a diode such as a free wheel diode (FWD) provided in direct contact with the transistor portion 70 in the front surface of the semiconductor substrate 10.

The semiconductor substrate 10 may be a silicon substrate, may be a silicon carbide substrate, or may be a nitride semiconductor substrate such as gallium nitride, or the like. The semiconductor substrate 10 in the present example is a silicon substrate.

The semiconductor device 100 in the present example includes a gate trench portion 40, a dummy trench portion 30, an emitter region 12, a base region 14, a contact region 15, and a well region 17, in the front surface of the semiconductor substrate 10. The semiconductor device 100 in the present example also includes an emitter electrode 52 and the gate metal layer 50, which are provided above the front surface of the semiconductor substrate 10.

The emitter electrode 52 is provided above the gate trench portion 40, the dummy trench portion 30, the emitter region 12, the base region 14, the contact region 15, and the well region 17. In addition, the gate metal layer 50 is provided above the gate trench portion 40 and the well region 17.

The emitter electrode 52 and the gate metal layer 50 are formed of a material including metal. At least some regions of the emitter electrode 52 may be formed of aluminum, aluminum-silicon alloy, or aluminum-silicon-copper alloy. At least some regions of the gate metal layer 50 may be formed of aluminum, aluminum-silicon alloy, or aluminum-silicon-copper alloy. The emitter electrode 52 and the gate metal layer 50 may have a barrier metal formed of titanium, titanium compound, or the like under the region formed of aluminum or the like. The emitter electrode 52 and the gate metal layer 50 are provided separately from each other.

The emitter electrode 52 and the gate metal layer 50 are provided above the semiconductor substrate 10 to sandwich an interlayer dielectric film 38. The interlayer dielectric film 38 is omitted from FIG. 2. A contact hole 54, a contact hole 55, and a contact hole 56 are provided to penetrate through the interlayer dielectric film 38.

The contact hole 55 connects a gate conductive portion within the gate trench portion 40 in the transistor portion 70 to the gate metal layer 50. A plug that is formed of tungsten or the like may be provided inside the contact hole 55.

The contact hole 56 connects a dummy conductive portion within the dummy trench portion 30 provided in the transistor portion 70 and the diode portion 80 to the emitter electrode 52. A plug that is formed of tungsten or the like may be provided inside the contact hole 56.

A connecting portion 25 electrically connects an electrode on the side of the front surface such as the emitter electrode 52 or the gate metal layer 50 to the semiconductor substrate 10. In an example, the connecting portion 25 is provided in a region including the interior of the contact hole 55, between the gate metal layer 50 and the gate conductive portion. The connecting portion 25 is also provided in a region including the interior of the contact hole 56, between the emitter electrode 52 and the dummy conductive portion. The connecting portion 25 is formed of a conductive material including metal such as tungsten, polysilicon doped with impurities, or the like. In addition, the connecting portion 25 may also have barrier metal such as titanium nitride. Here, the connecting portion 25 is formed of polysilicon (N+) doped with impurities of the N type. The connecting portion 25 is provided above the front surface of the semiconductor substrate 10 via a dielectric film such as an oxide film, or the like.

The gate trench portion 40 is arranged at a predetermined interval along a predetermined arrangement direction (the X axis direction in the present example). The gate trench portion 40 in the present example may have two extending portions 41 extending along the extending direction (in the present example, the Y axis direction) that is parallel to the front surface of the semiconductor substrate 10 and perpendicular to the arrangement direction and a connecting part 43 connecting the two extending portions 41.

At least a part of the connecting part 43 is preferably formed in a curved shape. By connecting end portions of the two extending portions 41 of the gate trench portion 40, concentration of electric fields at the end portions of the extending portions 41 can be reduced. At the connecting part 43 of the gate trench portion 40, the gate metal layer 50 may be connected to the gate conductive portion.

The dummy trench portion 30 is a trench portion which includes a dummy conductive portion provided therein and electrically connected to the emitter electrode 52. The dummy trench portion 30 is arranged similarly to the gate trench portion 40, at a predetermined interval along a predetermined arrangement direction (the X axis direction in the present example). Similar to the gate trench portion 40, the dummy trench portion 30 in the present example may have a U shape in the front surface of the semiconductor substrate 10. That is, the dummy trench portion 30 may have two extending portions 31 which extend along the extending direction and a connecting part 33 which connects two extending portions 31.

The transistor portion 70 in the present example has a structure in which one gate trench portion 40 and one dummy trench portion 30 are repeatedly arranged. That is, the transistor portion 70 in the present example has the gate trench portions 40 and the dummy trench portions 30 at a ratio of 1:1. For example, the transistor portion 70 has one extending portion 31 between two extending portions 41. In addition, the transistor portion 70 has two extending portions 31 adjacent to the gate trench portion 40.

It is noted however that the ratio of the gate trench portions 40 and the dummy trench portions 30 is not limited to the present example. The ratio of the gate trench portions 40 and the dummy trench portions 30 may be 2:3 or may be 2:4. Also, the transistor portion 70 may have a namely full gate configuration where the gate trench portions 40 are all provided, without any of the dummy trench portion 30.

The well region 17 is provided closer to the side of the front surface of the semiconductor substrate 10 than a drift region 18 which will be described below. The well region 17 is an example of the well region provided in the edge side of the semiconductor device 100. The well region 17 is of the P+ type as an example. The well region 17 is formed within a predetermined range from an end portion of the active region on a side in which the gate metal layer 50 is provided. A diffusion depth of the well region 17 may be deeper than depths of the gate trench portion 40 and the dummy trench portion 30. Some regions of the gate trench portion 40 and the dummy trench portion 30 on the side of the gate metal layer 50 are formed in the well region 17. The bottoms at the end of the extending direction of the gate trench portion 40 and the dummy trench portion 30 may be covered by the well region 17.

The contact hole 54 is formed above each region of the emitter region 12 and the contact region 15 in the transistor portion 70. The contact hole 54 is provided above the base region 14 in the diode portion 80. No contact holes 54 are provided above the well regions 17 provided at both ends in the Y axis direction. In this manner, one or more contact holes 54 are formed in the interlayer dielectric film. One or more contact holes 54 may be provided to extend in the extending direction. A plug 60 which will be described below is provided inside the contact hole 54.

The boundary portion 90 is a region in direct contact with the diode portion 80 in the transistor portion 70. That is, the boundary portion 90 is a portion of the transistor portion 70, and it has the same element structure as other regions of the transistor portion 70. As will be described below, the boundary portion 90 is a region provided with a lifetime control region 85 that is formed by irradiating a particle beam from the side of the front surface of the semiconductor substrate 10.

A mesa portion 71, a mesa portion 81, and a mesa portion 91 are mesa portions that are provided in direct contact with the trench portion in a plane parallel to the front surface of the semiconductor substrate 10. The mesa portion may be a portion of the semiconductor substrate 10 sandwiched between two adjacent trench portions, which is located from the front surface of the semiconductor substrate 10 to the depth of the deepest bottom portion of each trench portions. The extending portions of each trench portion may be regarded as one trench portion. That is, the region sandwiched between two extending portions may be set to be a mesa portion.

The mesa portion 71 is provided in direct contact with at least one of the dummy trench portion 30 or the gate trench portion 40 in the transistor portion 70. The mesa portion 71 has the well region 17, the emitter region 12, the base region 14, and the contact region 15, in the front surface of the semiconductor substrate 10. In the mesa portion 71, the emitter regions 12 and the contact regions 15 are alternately provided in the extending direction.

The mesa portion 81 is provided in a region sandwiched between the dummy trench portions 30 adjacent to each other in the diode portion 80. The mesa portion 81 in the present example has the base region 14 and has the well region 17 on the negative side in the Y axis direction, in the front surface of the semiconductor substrate 10. In the mesa portion 81, the contact region 15 may be provided at the front surface of the base region 14.

The base region 14 is a region provided on the side of the front surface of the semiconductor substrate 10 in the transistor portion 70 and the diode portion 80. The base region 14 is of the P− type as an example. The base region 14 may be provided at both end portions of the mesa portion 71 in the Y axis direction, in the front surface of the semiconductor substrate 10. Note that FIG. 2 only illustrates the end portion of the base region 14 on the negative side in the Y axis direction.

The emitter region 12 is a region of the same conductivity type as that of the drift region 18 and has a higher doping concentration than the drift region 18. The emitter region 12 in the present example is of the N+ type as an example. Examples of a dopant of the emitter region 12 include arsenic (As). The emitter region 12 is provided in contact with the gate trench portion 40 in the front surface of the mesa portion 71. The emitter region 12 may be provided to extend in the X axis direction from one of two trench portions sandwiching the mesa portion 71 to another of the two trench parts. The emitter region 12 is also provided below the contact hole 54.

In addition, the emitter region 12 may or may not be in contact with the dummy trench portion 30. The emitter region 12 in the present example is in contact with the dummy trench portion 30. The emitter region 12 may not be provided in the mesa portion 81.

The contact region 15 is a region of the same conductivity type as that of the base region 14 and has a higher doping concentration than the base region 14. The contact region 15 in the present example is of the P+ type as an example. The contact region 15 in the present example is provided at the front surface of the mesa portion 71. The contact region 15 may be provided to extend in the X axis direction from one of two trench portions sandwiching the mesa portion 71 to another of the two trench parts.

The contact region 15 may or may not be in contact with the gate trench portion 40. In addition, the contact region 15 may or may not be in contact with the dummy trench portion 30. In the present example, the contact region 15 is in contact with the dummy trench portion 30 and the gate trench portion 40. The contact region 15 is also provided below the contact hole 54.

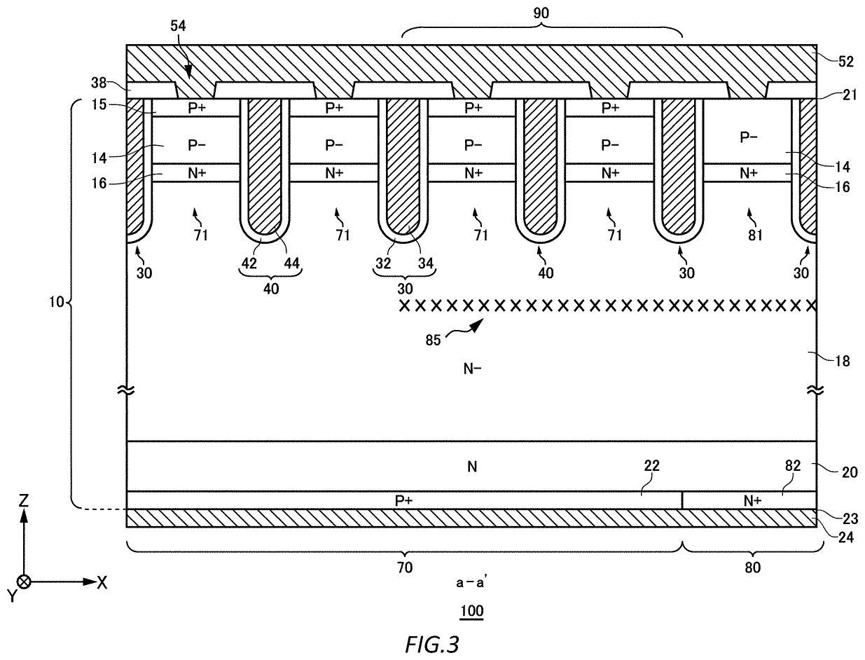

FIG. 3 is a drawing illustrating an example in a cross-section a-a′ of FIG. 2. The cross-section a-a′ is an XZ plane passing through the contact region 15 in the transistor portion 70. The semiconductor device 100 in the present example has the semiconductor substrate 10, the interlayer dielectric film 38, the contact region 15, and a collector electrode 24, in the cross-section a-a′. The emitter electrode 52 is formed above the semiconductor substrate 10 and the interlayer dielectric film 38.

The drift region 18 is a region provided in the semiconductor substrate 10. The drift region 18 in the present example is of the N− type as an example. The drift region 18 may be a region that has remained without other doping regions being formed in the semiconductor substrate 10. That is, the doping concentration of the drift region 18 may be a doping concentration of the semiconductor substrate 10.

A buffer region 20 is a region provided below the drift region 18. The buffer region 20 in the present example may be the same conductivity type as that of the drift region 18 and is of the N type, as an example. The doping concentration of the buffer region 20 is higher than the doping concentration of the drift region 18. The buffer region 20 may function as a field stop layer which prevents a depletion layer expanding from the side of the lower surface of the base region 14 from reaching the collector region 22 and the cathode region 82.

The collector region 22 is a region provided below the buffer region 20 in the transistor portion 70 and of the conductivity type different from that of the drift region 18. The cathode region 82 is a region provided below the buffer region 20 in the diode portion 80 and of the same conductivity type as that of the drift region 18. The boundary between the collector region 22 and the cathode region 82 is a boundary between the transistor portion 70 and the diode portion 80.

The collector electrode 24 is formed at a back surface 23 of the semiconductor substrate 10. The collector electrode 24 is formed of a conductive material such as metal.

The base region 14 is a region provided above the drift region 18 in the mesa portion 71 and the mesa portion 81, and is of a conductivity type different from that of the drift region 18. The base region 14 in the present example is of the P− type as an example. The base region 14 is provided in contact with the gate trench portion 40. The base region 14 may be provided in contact with the dummy trench portion 30.

The contact region 15 is provided between the base region 14 and a front surface 21. In another cross-section, the contact region 15 may be provided at the front surface 21 of the mesa portion 71. The contact region 15 in the present example is not provided in the mesa portion 81. The contact region 15 is provided in contact with the gate trench portion 40. The contact region 15 may or may not be in contact with the dummy trench portion 30.

An accumulation region 16 is a region provided closer to the front surface 21 of the semiconductor substrate 10 than the drift region 18. The accumulation region 16 in the present example is of the same conductivity type as that of the drift region 18, and is of the N+ type as an example. The accumulation region 16 is provided in the transistor portion 70 and the diode portion 80. It is noted however that the accumulation region 16 may not be provided.

In addition, the accumulation region 16 is provided in contact with the gate trench portion 40. The accumulation region 16 may or may not be in contact with the dummy trench portion 30. The doping concentration of the accumulation region 16 is higher than the doping concentration of the drift region 18. The dosage of ion implantation to the accumulation region 16 may be 1E12 cm⁻² or more and 1E13 cm⁻² or less. In addition, the dosage of ion implantation to the accumulation region 16 may also be 3E12 cm⁻² or more and 6E12 cm⁻² or less. Providing the accumulation region 16 can enhance the carrier injection enhancement effect (IE effect) to reduce an ON voltage of the transistor portion 70. Note that the character E represents a power of 10, and 1E12 cm⁻² represents 1×10 12 cm⁻², for example.

One or more gate trench portions 40 and one or more dummy trench portions 30 are provided at the front surface 21. Each trench portion is provided from the front surface 21 to the drift region 18. In a region where at least any of the emitter region 12, the base region 14, the contact region 15, or the accumulation region 16 is provided, each trench portion also penetrates through these regions to reach the drift region 18. The configuration of the trench portion penetrating through the doping region is not limited to that manufactured in the order of forming the doping region and then forming the trench portion. A structure in which the trench portion is formed and then the doping region is formed between the trench portions is also included in the structure in which the trench portion penetrates through the doping region.

The gate trench portion 40 has a gate trench provided at the front surface 21, a gate dielectric film 42, and a gate conductive portion 44. The gate dielectric film 42 is provided to cover an inner wall of the gate trench. The gate dielectric film 42 may be formed by oxidizing or nitriding a semiconductor on the inner wall of the gate trench. The gate conductive portion 44 is provided on an inner side of the gate dielectric film 42 inside the gate trench. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 in the front surface 21.

The gate conductive portion 44 includes a region opposing the adjacent base region 14 on the side of the mesa portion 71 by sandwiching the gate dielectric film 42 in a depth direction of the semiconductor substrate 10. When a predetermined voltage is applied to the gate conductive portion 44, a channel is formed to a surface layer being at a boundary within the base region 14 and in contact with the gate trench, due to an electron inversion layer.

The dummy trench portion 30 may have the same structure as the gate trench portion 40. The dummy trench portion 30 has a dummy trench, a dummy dielectric film 32, and a dummy conductive portion 34 which are formed on the side of the front surface 21. The dummy dielectric film 32 is provided to cover an inner wall of the dummy trench. The dummy conductive portion 34 is provided inside the dummy trench, and is provided on an inner side of the dummy dielectric film 32. The dummy dielectric film 32 insulates the dummy conductive portion 34 from the semiconductor substrate 10. The dummy trench portion 30 is covered by the interlayer dielectric film 38 in the front surface 21.

The interlayer dielectric film 38 is provided at the front surface 21. The emitter electrode 52 is provided above the interlayer dielectric film 38. The interlayer dielectric film 38 is provided with one or more contact holes 54 to electrically connect the emitter electrode 52 with the semiconductor substrate 10. Similarly, the contact hole 55 and the contact hole 56 may be provided to penetrate through the interlayer dielectric film 38.

In the drift region 18, the lifetime control region 85 including a lifetime killer is locally provided. The lifetime killer is a crystal defect that is formed at a predetermined depth position in the semiconductor substrate 10, for example, by implanting helium ions, hydrogen ions (protons), deuterium ions, or the like. The lifetime control region 85 promotes recombination of holes generated in the base region 14 and electrons injected from the cathode region 82 when the diode portion 80 is turned off, thereby suppressing a peak current at the time of reverse recovery.

The lifetime control region 85 in the present example is formed by irradiating proton or helium from the front surface 21 of the semiconductor substrate 10 by using a mask. As an example, proton or helium is irradiated through an opening of a mask in a state where a region in which the lifetime control region 85 is not formed is shielded with the mask. Proton or helium is not irradiated to the region shielded with the mask. Alternatively, the lifetime control region 85 may be formed by irradiating proton or helium to an entire surface from the front surface 21 of the semiconductor substrate 10 without using a mask.

In FIG. 3, peak positions in the Z axis direction of the concentration distribution of the lifetime killer are indicated by a symbol of “x”. The lifetime control region 85 may be provided to have a plurality of peaks of concentration distributions of the lifetime killer in the Z axis direction.

The lifetime control region 85 in the present example is continuously provided from the diode portion 80 across at least a portion of the transistor portion 70. In the transistor portion 70, a region provided with the lifetime control region 85 corresponds to the boundary portion 90. When the diode portion is conducting, there is generation of a hole current flowing not only from the base region 14 of the diode portion 80 but also from the base region 14 of the transistor portion 70 toward the cathode region 82. In the transistor portion 70, since the lifetime control region 85 is provided in the boundary portion 90, carrier elimination is promoted, and reverse recovery loss during turn-off is reduced.

Note that, in the gate trench portion 40 of the boundary portion 90, the gate dielectric film 42 is damaged when helium or proton is irradiated from the front surface 21 of the semiconductor substrate 10, and an interface state is changed. When a gate voltage is applied to the gate dielectric film 42 that has been irradiated, an inversion layer is easily formed in the base region 14 in direct contact with the irradiated gate dielectric film 42, than the gate dielectric film 42 that has not been irradiated. Therefore, in the boundary portion 90, a threshold voltage is decreased as compared to a region other than the boundary portion 90 of the transistor portion 70.

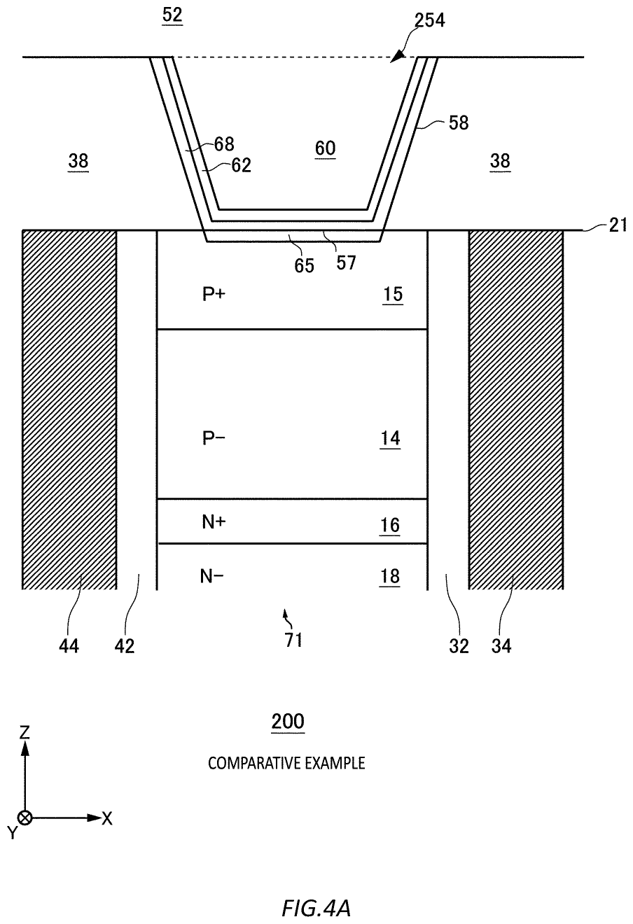

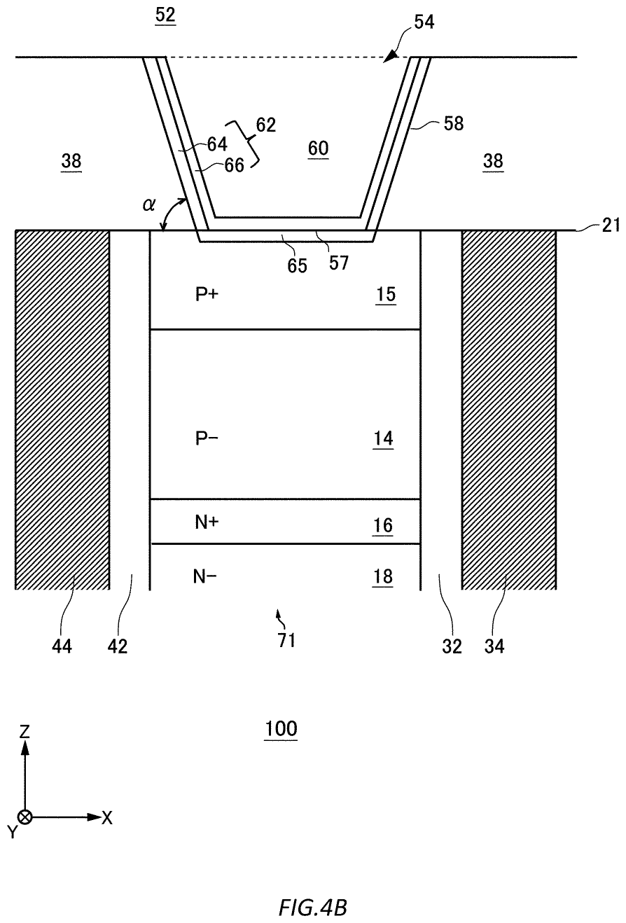

FIG. 4A illustrates an enlarged cross-sectional view of a semiconductor device 200 according to a comparative example. Here, a contact hole which is provided above the mesa portion will be mainly described. A contact hole 254 described herein corresponds to the contact hole 54 of the semiconductor device 100 described in FIG. 2 to FIG. 3, and the semiconductor device 200 has the same structure as the semiconductor device 100 except for the structure of the contact hole 254. Therefore, in FIG. 4A, components that are in common with the semiconductor device 100 are given the same signs, and descriptions will be omitted.

Note that, FIG. 4A illustrates the contact hole 254 provided above the mesa portion 71 between the gate trench portion 40 and the dummy trench portion 30 as an example, but other contact holes 254 also have the same structure. In addition, FIG. 4A illustrates the structure of the contact hole 254 in an XZ cross-section passing through the contact region 15, but the same structure may also be provided also in the XZ cross-section passing through the emitter region 12 or the like.

The contact hole 254 has a bottom surface 57 and a side wall 58. The contact hole 254 has a tapered shape in which the side wall 58 is tilted. However, the side wall 58 of the contact hole 254 may be provided substantially perpendicular to the front surface 21 of the semiconductor substrate 10. The bottom surface 57 may be a flat surface on the front surface 21 of the semiconductor substrate 10 as illustrated in FIG. 4A, or may be recessed in a concave shape toward the center.

The bottom surface 57 and the side wall 58 of the contact hole 254 are covered with a Ti layer 68, and a stacked TiN layer 62 is provided on the Ti layer 68. The Ti layer 68 and the TiN layer 62 function as barrier metal. The Ti layer 68 and the TiN layer 62 are formed from Ti/TiN sputtered inside the contact hole 254.

The plug 60 formed of a conductive material is provided via the Ti layer 68 and the TiN layer 62 inside the contact hole 254. As an example, the plug 60 is a tungsten film that is formed with a CVD method using WF6 gas or the like.

The semiconductor substrate 10 has a Ti silicide layer 65 in contact with the bottom surface 57 of the contact hole 254. That is, the Ti layer 68 contacts the interlayer dielectric film 38 in the side wall 58, and contacts the Ti silicide layer 65 in the bottom surface 57. The Ti silicide layer 65 is formed by attachment of Ti sputtered inside the contact hole 254 with a silicon of the semiconductor substrate 10. The Ti silicide layer 65 forms an ohmic contact between the barrier metal and the semiconductor substrate 10.

As described above, the semiconductor device 200 has the lifetime control region 85. Since the lifetime control region 85 is formed by irradiating a particle beam from the side of the front surface 21 of the semiconductor substrate 10, in the boundary portion 90, a threshold voltage is decreased due to damage on the gate dielectric film 42.

Such damage on the gate dielectric film 42 can be recovered by terminating a dangling bond with hydrogen anneal. However, due to a hydrogen occluding capacity of Ti, much of hydrogen passing through the interlayer dielectric film 38 are occluded in the Ti layer 68. As a result, damage recovery of the gate dielectric film 42 is inhibited.

FIG. 4B illustrates an example of an enlarged cross-sectional view of the semiconductor device 100 according to the embodiment. Here, as in the case of FIG. 4A, the contact hole 54 provided above the mesa portion 71 will be described. Thus, components that are in common with FIG. 4A are given the same signs, and descriptions will be omitted.

The contact hole 54 in the present example has a tapered shape in which the side wall 58 is tilted. A taper angle α of the contact hole 54 is 80 degrees or more and less than 90 degrees. Here, the taper angle α refers to an angle formed with the side wall 58 and the front surface 21 of the semiconductor substrate 10. By setting the taper angle α to such range, formation of a Ti layer in the side wall 58 is suppressed.

The side wall 58 of the contact hole 54 is covered with a first TiN layer 64, and a second TiN layer 66 is stacked on the first TiN layer 64. The first TiN layer 64 and the second TiN layer 66 singularly or collectively constitute the TiN layer 62 as illustrated in FIG. 4A, and function as barrier metal.

The first TiN layer 64 covers an entire surface of the side wall 58 of the contact hole 54, and contacts the interlayer dielectric film 38 in the side wall 58. On the other hand, the first TiN layer 64 is not provided for the bottom surface 57 of the contact hole 54. The bottom surface 57 of the contact hole 54 is provided with the second TiN layer 66. That is, the second TiN layer 66 covers the first TiN layer 64 in the side wall 58 of the contact hole 54, and is provided at the upper surface of the Ti silicide layer 65 of the semiconductor substrate 10, in the bottom surface 57 of the contact hole 54.

The first TiN layer 64 is formed by nitriding of Ti ions deposited on the side wall 58 among Ti ions implanted into the bottom surface 57 of the contact hole 54. On the other hand, Ti ions deposited on the bottom surface 57 of the contact hole 54 form the Ti silicide layer 65 by being attached with the silicon of the semiconductor substrate 10. The second TiN layer 66 is formed from TiN sputtered inside the contact hole 54, after the formation of the first TiN layer 64 and the Ti silicide layer 65.

A thickness of the Ti silicide layer 65 may be 10 nm or more and 100 nm or less, or may be 20 nm or more and 30 nm or less. By providing the Ti silicide layer 65 in such range, it is possible to maintain production efficiency while forming a contact. A thickness of the first TiN layer 64 may be less than ½ or may be less than ⅕ of the thickness of the Ti silicide layer 65.

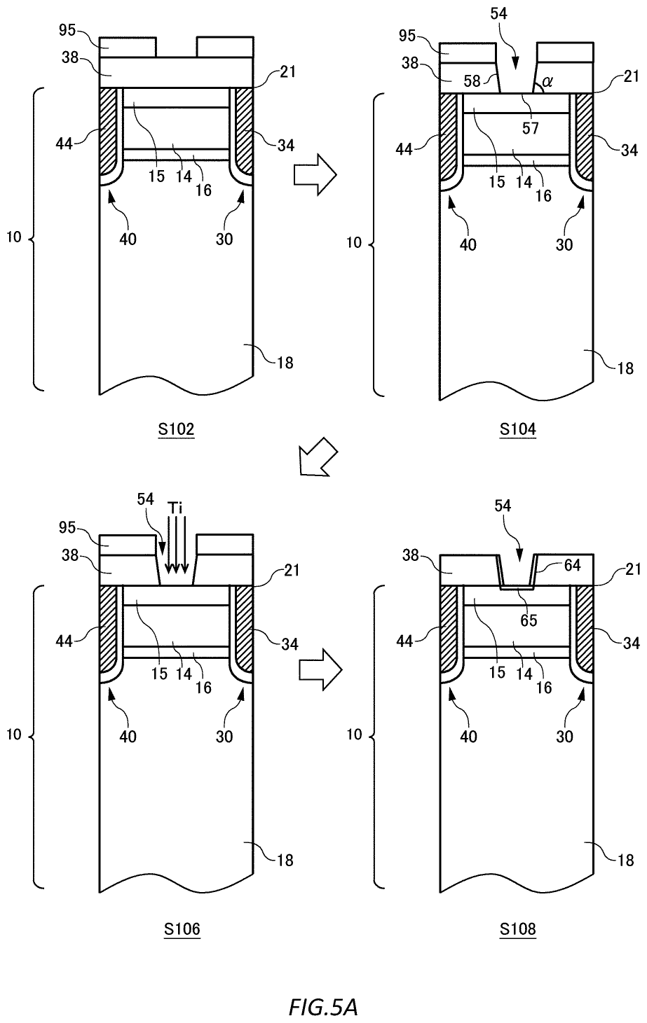

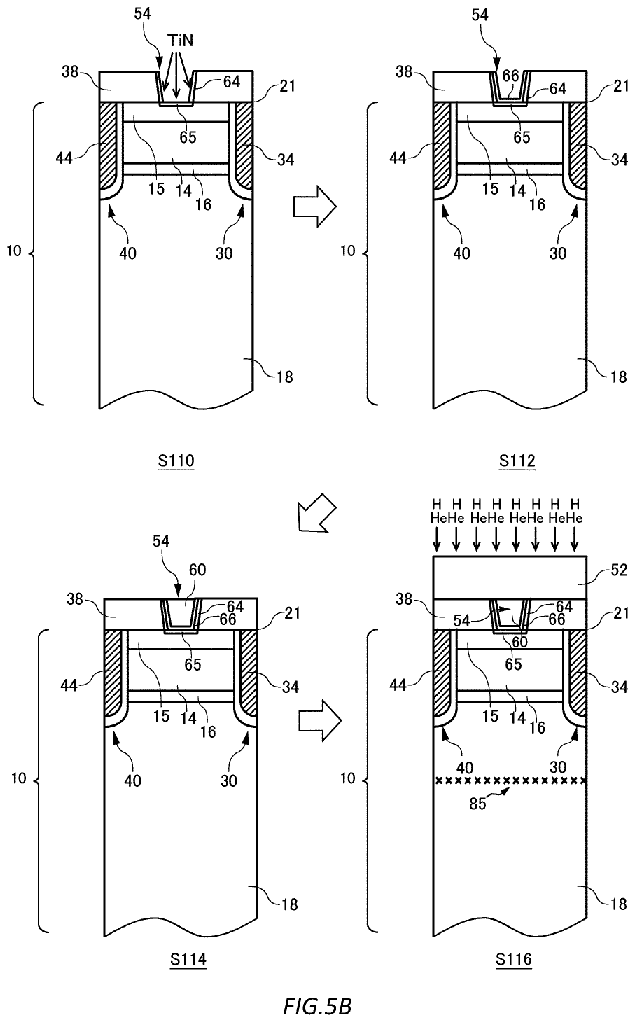

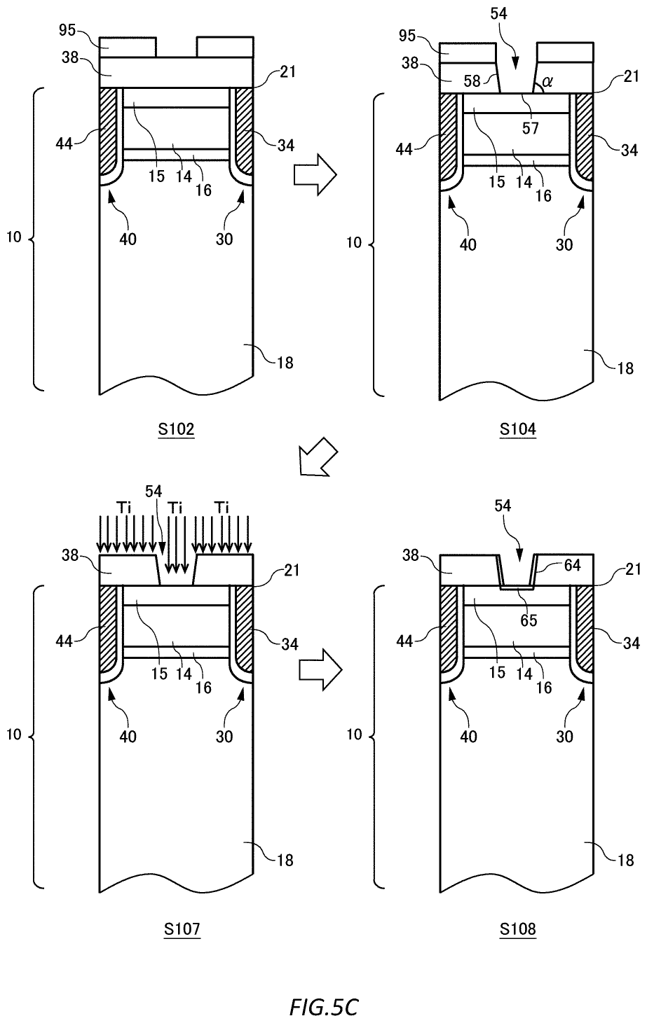

FIG. 5A to FIG. 5B are drawings illustrating examples of a manufacturing method of the semiconductor device 100 according to the embodiment. Here, a process of forming the contact hole 54, the first TiN layer 64, the Ti silicide layer 65, the second TiN layer 66, and the plug 60 in this order on the semiconductor substrate 10 in which an element structure is formed at the front surface 21 and the interlayer dielectric film 38 is provided, will be described.

In Step S102, a resist mask 95 is formed on the interlayer dielectric film 38. Then, in Step S104, the contact hole 54 is formed by etching the interlayer dielectric film 38 from the upper surface to the front surface 21 of the semiconductor substrate 10 via the resist mask 95. Here, etching is performed such that the taper angle α of the contact hole 54 becomes 80 degrees or more and less than 90 degrees. By forming the contact hole 54 with the taper angle α in such range, deposition of Ti ions on the side wall 58 is suppressed in the subsequent ion implantation process. After formation of the contact hole 54, wet etching may be performed on the bottom surface 57 and the side wall 58 of the contact hole 54 with a BHF aqueous solution to remove a natural oxide film that is formed at the top surface.

In Step S106, Ti is ion-implanted into the bottom surface of the contact hole 54 via the resist mask 95. Here, the dosage of Ti ions may be 1E15/cm² or more and 5E17/cm² or less, or may be 1E17/cm² or less. The dosage of Ti ions is one of parameters deciding the thickness of the Ti silicide layer 65. By implanting Ti ions with such dosage, in the subsequent process, excess Ti which is not silicified is prevented from remaining at the bottom surface 57 or the side wall 58 of the contact hole 54 while the Ti silicide layer 65 whose thickness is sufficient to form a contact is formed.

An implantation acceleration voltage of Ti ions may be 1 keV or more and 100 keV or less, or may be 15 keV or more and 30 keV or less. The implantation acceleration voltage of Ti ions is also one of the parameters deciding the thickness of the Ti silicide layer 65. By implanting Ti ions with such implantation acceleration voltage, while the Ti silicide layer 65 having a sufficient thickness is formed, the Ti silicide layer 65 is formed at a position deeper than the front surface 21 of the semiconductor substrate 10, thereby preventing the silicon of the semiconductor substrate 10 from contacting the bottom surface 57 of the contact hole 54.

In addition, since ion implantation easily keeps directionality as compared to sputtering, Ti can be selectively deposited on the bottom surface 57 of the contact hole 54, and deposition on the side wall 58 can be suppressed. Furthermore, although sputtering cannot use a resist mask as it is a processing with a temperature higher than a heat resisting temperature of a resist, ion implantation can use a resist mask.

After the ion implantation of Ti, the resist mask 95 is removed. At this time, unnecessary Ti, compounds thereof, and the like remaining on the resist mask 95 can be removed together with the resist mask 95.

In Step S108, the Ti silicide layer 65 is formed at the bottom surface 57 of the contact hole 54 with anneal. Anneal may be Rapid Thermal Anneal (RTA). The thickness of the Ti silicide layer 65 may be 10 nm or more and 100 nm or less, or may be 20 nm or more and 30 nm or less. By providing the Ti silicide layer 65 in such range, it is possible to maintain production efficiency while forming a contact.

In addition, ion-implanted Ti in the previous Step S106 slightly deposits also on the side wall 58 of the contact hole 54. In Step S108, Ti ions deposited on the side wall 58 of the contact hole 54 are nitrided with anneal, and the first TiN layer 64 is formed. That is, since Ti ions deposited on the bottom surface 57 of the contact hole 54 form the Ti silicide layer 65 by being attached with the silicon, and Ti ions deposited on the side wall 58 form the first TiN layer 64 by being attached with nitrogen, a Ti layer is not formed. The thickness of the first TiN layer 64 may be less than ½ or may be less than ⅕ of the thickness of the Ti silicide layer 65.

In Step S110, TiN is sputtered in the contact hole 54. Then, in Step S112, the second TiN layer 66 is formed on the first TiN layer 64 and the Ti silicide layer 65 with anneal. After this, in Step S114, a conductive material is embedded into the contact hole 54 to form the plug 60. As an example, the plug 60 is formed by CVD-growing tungsten on the second TiN layer 66. After this, the emitter electrode 52 is formed on the interlayer dielectric film 38.

After this, in Step S116, the lifetime control region 85 is formed from the side of the front surface 21 of the semiconductor substrate 10. Here, proton or helium is irradiated from above the emitter electrode 52. Proton or helium may be irradiated through an opening of a mask in a state where a region in which the lifetime control region 85 is not formed (a region other than the boundary portion 90 of the transistor portion 70) is shielded with the mask. Alternatively, the lifetime control region 85 may be formed by irradiating proton or helium to the entire surface of the semiconductor substrate 10 without using a mask.

FIG. 5C is a drawing illustrating another example of the manufacturing method of the semiconductor device 100 according to the embodiment. Here, differences from the manufacturing method illustrated in FIG. 5A will be mainly described. In the present example, after forming the contact hole 54 in Step S104, the resist mask 95 is removed. Then, in Step S107, Ti is ion-implanted into the entire surface from the side of the front surface 21 of the semiconductor substrate 10.

That is, in the present example, since Ti is ion-implanted without the resist mask 95, Ti is deposited not only on the bottom surface 57 and the side wall 58 of the contact hole 54 but also on the interlayer dielectric film 38. Ti deposited on the interlayer dielectric film 38 may be removed by etching.

The dosage of Ti ions may be as described in relation to Step S106 in FIG. 5A. Then, Step S108 will be performed, however, the following processes are in common with FIG. 5A to FIG. 5B, and thus descriptions will be omitted.

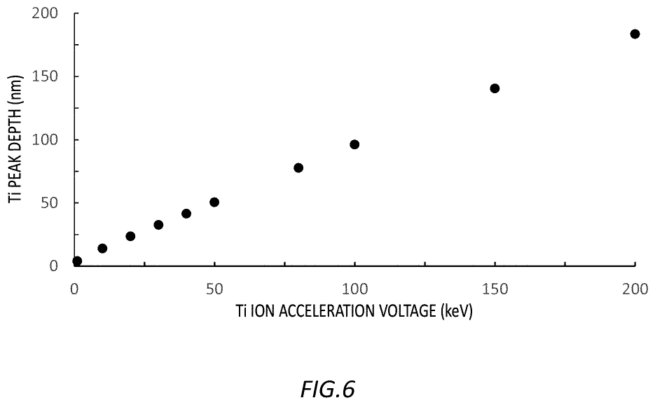

FIG. 6 is a drawing illustrating a relationship between the implantation acceleration voltage and the implantation depth of Ti ions. FIG. 6 illustrates a graph putting the implantation acceleration voltage (keV) of Ti ions on the horizontal axis, and the implantation depth (nm) of Ti ions on the vertical axis. Here, the implantation depth of Ti ions refers to a peak depth of the implanted Ti ions.

As an example, if the implantation acceleration voltage of Ti ions is set to 15 keV to 30 keV, the implantation depth would be 20 nm to 30 nm, and the Ti silicide layer 65 having a thickness of 20 nm to 30 nm can be obtained. In addition, if the implantation acceleration voltage of Ti ions is set to 1 keV to 50 keV, the implantation depth would be 10 nm to 50 nm, and the Ti silicide layer 65 having a thickness of 10 nm to 50 nm can be obtained.

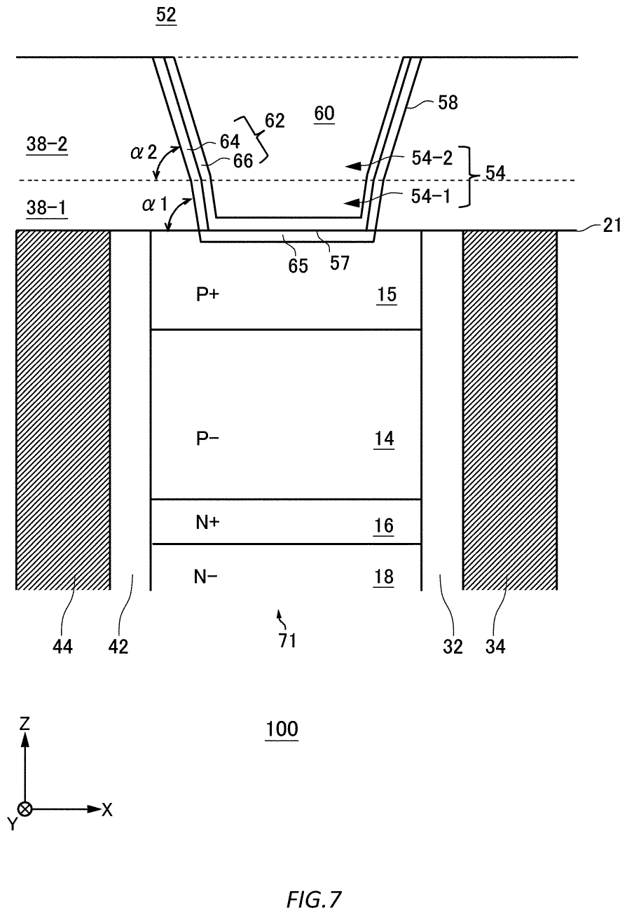

FIG. 7 illustrates an example of an enlarged cross-sectional view of the semiconductor device 100 according to the embodiment. As illustrated in FIG. 7, the contact hole 54 may have a first portion 54-1 on the side of the front surface 21 of the semiconductor substrate 10, and a second portion 54-2 which is positioned on the first portion 54-1, where the second portion 54-2 has a taper angle different from that of the first portion 54-1. The interlayer dielectric film 38 may have a stacked structure with a first layer 38-1 and a second layer 38-2 stacked on the first layer 38-1, where the second layer 38-2 corresponds to the second portion 54-2 and is formed of a material different from that of the first layer 38-1 corresponding to the first portion 54-1. In the present example, the first layer 38-1 is an HTO film, and the second layer 38-2 is a BPSG film.

In the present example, a taper angle α1 of the first portion 54-1 is greater than a taper angle α2 of the second portion 54-2. The bottom surface 57 and the side wall 58 of the contact hole 54 are wet-etched with a BHF aqueous solution before the process of forming barrier metal, and an etching rate of the second layer 38-2 with respect to the BHF aqueous solution is greater than that of the first layer 38-1. Therefore, the contact hole 54 in the present example has a step-like structure in which a cross-section in the depth direction of the second portion 54-2 is greater than a cross-section in the depth direction of the first portion 54-1, corresponding to the first layer 38-1 and the second layer 38-2 of the interlayer dielectric film 38.

In this manner, according to the present example, Ti is ion-implanted into the bottom surface 57 of the contact hole 54. Since ion implantation easily keeps directionality as compared to sputtering, Ti can be selectively deposited on the bottom surface 57 of the contact hole 54, and deposition of Ti on the side wall 58 can be suppressed. Therefore, hydrogen will not be occluded in a Ti layer of the contact hole 54, and damage on the gate dielectric film 42 of the boundary portion 90 can be recovered and decrease in a threshold voltage can be prevented.

In addition, since decrease in a threshold voltage can be prevented in this manner, the lifetime control region 85 can be formed by irradiating proton or helium from the front surface 21 of the semiconductor substrate 10. Therefore, an implantation depth can be made little as compared to when proton or helium is irradiated from the back surface 23 of the semiconductor substrate 10, and thus a manufacturing device of a lifetime killer can be miniaturized.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that embodiments added with such alterations or improvements can be included in the technical scope of the present invention.

The operations, procedures, steps, stages, or the like of each processing performed by a device, system, program, and method shown in the claims, embodiments, or drawings can be performed in any order as long as the order is not indicated by “prior to,” “before,” or the like and as long as the output from a previous processing is not used in a later processing. Even if the operation flow is described using phrases such as “first” or “next” in the claims, embodiments, or drawings, it does not necessarily mean that the processing must be performed in this order.

### EXPLANATION OF REFERENCES

10 . . . semiconductor substrate, 12 . . . emitter region, 14 . . . base region, 15 . . . contact region, 16 . . . accumulation region, 17 . . . well region, 18 . . . drift region, 21 . . . front surface, 22 . . . collector region, 23 . . . back surface, 24 . . . collector electrode, 25 . . . connecting portion, 30 . . . dummy trench portion, 31 . . . extending portion, 32 . . . dummy dielectric film, 33 . . . connecting part, 34 . . . dummy conductive portion, 38 . . . interlayer dielectric film, 40 . . . gate trench portion, 41 . . . extending portion, 42 . . . gate dielectric film, 43 . . . connecting part, 44 . . . gate conductive portion, 50 . . . gate metal layer, 52 . . . emitter electrode, 54 . . . contact hole, 55 . . . contact hole, 56 . . . contact hole, 57 . . . bottom surface, 58 . . . side wall, 60 . . . plug, 62 . . . TiN layer, 64 . . . first TiN layer, 65 . . . Ti silicide layer, 66 . . . second TiN layer, 68 . . . Ti layer, 70 . . . transistor portion, 71 . . . mesa portion, 80 . . . diode portion, 81 . . . mesa portion, 82 . . . cathode region, 85 . . . lifetime control region, 90 . . . boundary portion, 91 . . . mesa portion, 95 . . . resist mask, 100 . . . semiconductor device, 102 . . . end side, 160 . . . active region, 162 . . . edge terminal structure portion, 200 . . . semiconductor device, 254 . . . contact hole.

What is claimed is:

1. A manufacturing method of a semiconductor device, comprising:
forming a lifetime control region from a side of a front surface of a semiconductor substrate;
ion-implanting Ti into a bottom surface of a contact hole provided so as to penetrate through an interlayer dielectric film arranged on the front surface of the semiconductor substrate; and
forming a Ti silicide layer at the bottom surface of the contact hole with anneal.

2. The manufacturing method of the semiconductor device according to claim 1, wherein
in the ion-implanting, a dosage of Ti is 1E15/cm² or more and 5E17/cm² or less.

3. The manufacturing method of the semiconductor device according to claim 1, wherein
in the ion-implanting, a dosage of Ti is 1E17/cm² or less.

4. The manufacturing method of the semiconductor device according to claim 1, wherein
in the ion-implanting, an implantation acceleration voltage of Ti is 1 keV or more and 100 keV or less.

5. The manufacturing method of the semiconductor device according to claim 4, wherein
in the ion-implanting, the implantation acceleration voltage of Ti is 15 keV or more and 30 keV or less.

6. The manufacturing method of the semiconductor device according to claim 1, wherein
a first TiN layer in which ion-implanted Ti is nitrided is formed at a side wall of the contact hole, and
a thickness of the first TiN layer is less than ½ of a thickness of the Ti silicide layer.

7. The manufacturing method of the semiconductor device according to claim 6, wherein
the thickness of the first TiN layer is less than ⅕ of the thickness of the Ti silicide layer.

8. The manufacturing method of the semiconductor device according to claim 6,
further comprising after the forming the Ti silicide layer, sputtering TiN in the contact hole, and forming a second TiN layer on the first TiN layer and the Ti silicide layer with anneal.

9. The manufacturing method of the semiconductor device according to claim 8,
further comprising after the forming the second TiN layer, embedding a conductive material into the contact hole.

10. The manufacturing method of the semiconductor device according to claim 1, comprising:
forming a resist mask;
ion-implanting Ti into the bottom surface of the contact hole via the resist mask; and
removing remaining Ti by removing the resist mask.

11. The manufacturing method of the semiconductor device according to claim 1, wherein
the semiconductor device is an RC-IGBT in which a transistor portion and a diode portion are provided for the semiconductor substrate.

12. A semiconductor device, comprising:
a semiconductor substrate having a transistor portion and a diode portion; and
an interlayer dielectric film arranged on a front surface of the semiconductor substrate, a contact hole being provided so as to penetrate through the interlayer dielectric film, wherein
the semiconductor substrate has a lifetime control region formed from the front surface of the semiconductor substrate, from the diode portion across at least a portion of the transistor portion,
a Ti silicide layer is provided at a bottom surface of the contact hole, and
at a side wall of the contact hole, a TiN layer is provided in contact with the interlayer dielectric film.

13. The semiconductor device according to claim 12, wherein
the TiN layer has a first TiN layer provided in contact with the side wall of the contact hole, and a second TiN layer different from the first TiN layer which is provided so as to cover the first TiN layer in the side wall of the contact hole.

14. The semiconductor device according to claim 13, wherein
the second TiN layer is provided at an upper surface of the Ti silicide layer.

15. The semiconductor device according to claim 12, wherein
the TiN layer covers an entire surface of the side wall of the contact hole.

16. The semiconductor device according to claim 12, wherein
the TiN layer is further provided at an upper surface of the Ti silicide layer.

17. The semiconductor device according to claim 12, wherein
a thickness of the Ti silicide layer is 10 nm or more and 100 nm or less.

18. The semiconductor device according to claim 17, wherein
the thickness of the Ti silicide layer is 20 nm or more and 30 nm or less.

19. The semiconductor device according to claim 12, wherein
a taper angle of the contact hole is 80 degrees or more and less than 90 degrees.

20. The semiconductor device according to claim 12, wherein
the contact hole has a first portion on a side of the front surface of the semiconductor substrate, and a second portion which is positioned on the first portion, wherein the second portion has a taper angle different from that of the first portion.

21. The semiconductor device according to claim 20, wherein
the interlayer dielectric film has a stacked structure with a first layer and a second layer stacked on the first layer, wherein the second layer corresponds to the second portion and is formed of a material different from that of the first layer corresponding to the first portion.

22. The semiconductor device according to claim 21, wherein
the first layer is an HTO film.
